(19) United States
(12) Patent Application Publication
(10) Pub. No.: US 2018/0269426 A1
(43) Pub. Date: Sep. 20, 2018

(54) ELECTROLUMINESCENCE DEVICE

(71) Applicant: Sharp Kabushiki Kaisha, Sakai City, Osaka (JP)

(72) Inventors: Tetsuya OKAMOTO, Sakai City (JP); Takeshi HIRASE, Sakai City (JP); Takashi OCHI, Sakai City (JP); Tohru SENOO, Sakai City (JP); Tohru SONODA, Sakai City (JP); Mamoru ISHIDA, Sakai City (JP)

(21) Appl. No.: 15/762,131

(22) PCT Filed: Sep. 26, 2016
(86) PCT No.: PCT/JP2016/078173

§ 371 Date: Mar. 22, 2018

(30) Foreign Application Priority Data
Oct. 1, 2015 (JP) 2015-196163

(51) Int. Cl. H01L 51/52; H01L 27/32; H01L 51/00

(52) U.S. Cl. CPC H01L 51/5253; H01L 27/3244; H01L 27/323; H01L 2251/5338; H01L 27/322; H01L 51/0097

(57) ABSTRACT

An organic EL display device including: a base material being flexible; an organic EL element (electroluminescence element) provided on the base material; a first moisture-proof film and a TFT layer provided in sequence on the base material between the base material and the organic EL element; and a first sealing film configured to seal the organic EL element. In the organic EL display device, a stress adjustment layer configured to adjust a neutral face of the organic EL display device is provided, and the neutral face is positioned between a lower face of the first moisture-proof film and an upper face of the first sealing film.

### TECHNICAL FIELD

The present invention relates to an electroluminescence device including an electroluminescence (EL) element.

### BACKGROUND ART

In recent years, flat panel displays have been utilized in various products and fields, and there are demands for flat panel displays having even larger sizes, even higher picture quality, and even lower power consumption.

In view of such circumstances, organic electroluminescence (referred to as EL below) display devices provided with organic EL elements utilizing the electro luminescence of organic materials are attracting much attention as flat panel displays due to their excellent qualities, such as low voltage driving, high responsiveness, and self-luminosity, while being in a completely solid state.

For example, in the case of an active-matrix organic EL display device, a thin-filmed organic EL element is provided on a (support) substrate on which a thin film transistor (TFT) is disposed. The organic EL element includes an organic EL layer including a light-emitting layer layered between a pair of electrodes. The TFT is connected with one of the pair of electrodes. Then, voltage is applied across the pair of electrodes to make the light-emitting layer emit light, whereby image display is performed.

Further, in this kind of known organic EL display device described above, in order to prevent deterioration of the organic EL element caused by moisture or oxygen, a known sealing film may be provided for the organic EL element.

Furthermore, in this kind of known organic EL display device described above, in order to constitute a (bendable) device that can be repeatedly bent, a known flexible base material may be used as a support substrate to support the organic EL element.

In the known organic EL display devices described above, a configuration has been proposed in which, in order to prevent the permeation of moisture from a base material side, a moisture-proof film is provided between the base material and a TFT layer where the TFT is disposed, as disclosed in the following PTL 1, for example. Then, in this known organic EL display device, it is stated that the deterioration of the organic EL element caused by moisture can be suppressed.

### CITATION LIST

### Patent Literature

PTL 1: JP 2004-327402 A

### SUMMARY OF INVENTION

### Technical Problem

In the above-discussed known organic EL display device, two moisture-proof films (the sealing film and moisture-proof film) sandwiching the organic EL element (electroluminescence element) are each configured with a layered structure of an inorganic film and an organic film.

However, in the known organic EL display device, an abnormal incident, such as a fracture in the inorganic film included in each of the moisture-proof films, occurs in some case when the stated organic EL display device is bent. Thus, in this known organic EL display device, a problem occurs in which the organic EL element deteriorates in some case.

In light of the foregoing, it is an object of the present invention to provide an electroluminescent device excellent in reliability that can prevent the deterioration of the electroluminescent element even in a case where the stated device is bent.

### Solution to Problem

In order to achieve the above object, an electroluminescence device according to the present invention is an electroluminescence device including a base material being flexible; and a plurality of layers including an electroluminescence element, disposed on the base material, the plurality of layers further including:

a first moisture-proof film provided on a surface on the electroluminescence element side of the base material;

a TFT layer provided on a surface on the electroluminescence element side of the first moisture-proof film, the TFT layer including a thin film transistor configured to perform switching operation on the electroluminescence element;

a first sealing film provided to cover the electroluminescence element and configured to seal the electroluminescence element;

a hard coat film configured to protect a surface of the electroluminescence device; and

a stress adjustment layer configured to adjust a neutral face of the electroluminescence device,

wherein the neutral face is positioned between a lower face of the first moisture-proof film and an upper face of the first sealing film.

In the case of the electroluminescence device having the configuration stated above, the electroluminescence element and the TFT layer are sandwiched between the first moisture-proof film and the first sealing film. Further, the stress adjustment layer is provided for adjusting the neutral face of the electroluminescence device. The neutral face is positioned between the lower face of the first moisture-proof film and the upper face of the first sealing film. In this manner, in contrast to the known example described above, such a highly reliable electroluminescent device can be constituted that can prevent the occurrence of abnormal incidents such as a fracture in the first moisture-proof film or the first sealing film, and also prevent the deterioration of the electroluminescent element, even in the case where the electroluminescence device is bent.

In the above-discussed electroluminescence device, the neutral face may be set to an intermediate position between the lower face of the first moisture-proof film and the upper face of the first sealing film.

In this case, the occurrence of abnormal incidents such as a fracture in the first moisture-proof film or the first sealing film can be prevented with certainty even in the case where the electroluminescence device is bent. As a result, the electroluminescence device more excellent in reliability that is capable of surely preventing the deterioration of the electroluminescence element can be easily constituted.

In the above-discussed electroluminescence device, it is preferable that Young's modulus and a thickness of each of the plurality of layers be set to make a distortion rate of each of the first moisture-proof film and the first sealing film become not greater than 1% when the electroluminescence device is bent with a radius of curvature of 0.5 mm, where the radius of curvature is a radius in a thickness direction of the electroluminescence device.

In this case, the occurrence of abnormal incidents such as a fracture in the first moisture-proof film or the first sealing film can be prevented with more certainty even in the case where the electroluminescence device is bent with the radius of curvature being 0.5 mm.

In the above-discussed electroluminescence device, the plurality of layers may further include a second moisture-proof film provided on a surface of the base material on an opposite side to the electroluminescence element side, and

the neutral face may be positioned between a lower face of the second moisture-proof film and the upper face of the first sealing film.

In this case, the occurrence of abnormal incidents such as a fracture in the first moisture-proof film, the first sealing film, or the second moisture-proof film can be prevented even in the case where the electroluminescence device is bent. In addition, the second moisture-proof film makes it possible to prevent the permeation of moisture or the like from the opposite side of the base material relative to the electroluminescence element side, whereby the electroluminescence device more excellent in reliability can be easily constituted.

In the above-discussed electroluminescence device, the neutral face may be set to an intermediate position between the lower face of the second moisture-proof film and the upper face of the first sealing film.

In this case, the occurrence of abnormal incidents such as a fracture in the first moisture-proof film, the first sealing film, or the second moisture-proof film can be prevented with certainty even in the case where the electroluminescence device is bent. As a result, the electroluminescence device more excellent in reliability that is capable of surely preventing the deterioration of the electroluminescence element can be easily constituted.

In the above-discussed electroluminescence device, it is preferable that Young's modulus and a thickness of each of the plurality of layers be set to make a distortion rate of each of the first moisture-proof film, the first sealing film, and the second moisture-proof film become not greater than 1% when the electroluminescence device is bent with a radius of curvature of 1.1 mm, where the radius of curvature is a radius in a thickness direction of the electroluminescence device.

In this case, the occurrence of abnormal incidents such as a fracture in the first moisture-proof film, the first sealing film, or the second moisture-proof film can be more surely prevented even in the case where the electroluminescence device is bent with the radius of curvature being 1.1 mm.

In the above-discussed electroluminescence device, the plurality of layers may further include a second sealing film provided in an upper portion of the first sealing film, the second sealing film being configured to seal the electroluminescence element, and

the neutral face may be positioned between the lower face of the first moisture-proof film and an upper face of the second sealing film.

In this case, the occurrence of abnormal incidents such as a fracture in the first moisture-proof film, the first sealing film, or the second sealing film can be prevented even in the case where the electroluminescence device is bent. In addition, the second sealing film makes it possible to prevent the permeation of moisture or the like from the electroluminescence element side of the base material, whereby the electroluminescence device more excellent in reliability can be easily constituted.

In the above-discussed electroluminescence device, the neutral face may be set to an intermediate position between the lower face of the first moisture-proof film and the upper face of the second sealing film.

In this case, the occurrence of abnormal incidents such as a fracture in the first moisture-proof film, the first sealing film, or the second sealing film can be prevented with certainty even in the case where the electroluminescence device is bent. As a result, the electroluminescence device more excellent in reliability that is capable of surely preventing the deterioration of the electroluminescence element can be easily constituted.

In the above-discussed electroluminescence device, it is preferable that Young's modulus and a thickness of each of the plurality of layers be set to make a distortion rate of each of the first moisture-proof film, the first sealing film, and the second sealing film become not greater than 1% when the electroluminescence device is bent with a radius of curvature of 0.8 mm, where the radius of curvature is a radius in a thickness direction of the electroluminescence device.

In this case, the occurrence of abnormal incidents such as a fracture in the first moisture-proof film, the first sealing film, or the second sealing film can be more surely prevented even in the case where the electroluminescence device is bent with the radius of curvature being 0.8 mm.

In the above-discussed electroluminescence device, the plurality of layers may further include a second moisture-proof film provided on a surface of the base material on the opposite side to the electroluminescence element side and a second sealing film provided in an upper portion of the first sealing film, the second sealing film being configured to seal the electroluminescence element, and

the neutral face may be positioned between a lower face of the second moisture-proof film and an upper face of the second sealing film.

In this case, the occurrence of abnormal incidents such as a fracture in the first moisture-proof film, the first sealing film, the second moisture-proof film, or the second sealing film can be prevented even in the case where the electroluminescence device is bent. In addition, the second moisture-proof film and the second sealing film make it possible to prevent the permeation of moisture or the like from the opposite side of the base material relative to the electroluminescence element side and from the electroluminescence element side of the base material, whereby the electroluminescence device more excellent in reliability can be easily constituted.

In the above-discussed electroluminescence device, the neutral face may be set to an intermediate position between the lower face of the second moisture-proof film and the upper face of the second sealing film.

In this case, the occurrence of abnormal incidents such as a fracture in the first moisture-proof film, the first sealing film, the second moisture-proof film, or the second sealing film can be prevented with certainty even in the case where the electroluminescence device is bent. As a result, the electroluminescence device more excellent in reliability that is capable of surely preventing the deterioration of the electroluminescence element can be easily constituted.

In the above-discussed electroluminescence device, it is preferable that Young's modulus and a thickness of each of the plurality of layers be set to make a distortion rate of each of the first moisture-proof film, the first sealing film, the second moisture-proof film, and the second sealing film become not greater than 1% when the electroluminescence device is bent with a radius of curvature of 1.5 mm, where the radius of curvature is a radius in a thickness direction of the electroluminescence device.

In this case, the occurrence of abnormal incidents such as a fracture in the first moisture-proof film, the first sealing film, the second moisture-proof film, or the second sealing film can be more surely prevented even in the case where the electroluminescence device is bent with the radius of curvature being 1.5 mm.

In the above-discussed electroluminescence device, it is preferable that Young's modulus and a thickness of each of the plurality of layers be set to make a distortion rate of each of the hard coat film and the stress adjustment layer become not greater than 4% when the electroluminescence device is bent with a radius of curvature of 3.0 mm, where the radius of curvature is a radius in the thickness direction of the electroluminescence device.

In this case, the occurrence of abnormal incidents such as a fracture in the hard coat film or the stress adjustment layer can be prevented with more certainty even in the case where the electroluminescence device is bent with the radius of curvature being 3.0 mm.

Further, in the above-discussed electroluminescence device, the hard coat film may be formed of a hard coat layer and a base material layered together, or formed of only a hard coat layer.

In this case, the surface of the electroluminescence device can be protected with certainty, thereby making it possible to protect the electroluminescence element with ease.

### Advantageous Effects of Invention

According to the present invention, a highly reliable electroluminescence device capable of preventing the deterioration of the electroluminescent element can be provided even in the case where the stated electroluminescence device is bent.

### BRIEF DESCRIPTION OF DRAWINGS

FIG. 1 is a plan view illustrating an organic EL display device according to a first embodiment of the present invention.

FIG. 2 is a cross-sectional view taken along a II-II line in FIG. 1.

FIG. 3 is a cross-sectional view taken along a III-III line in FIG. 1.

FIG. 4 is a diagram explaining the configuration of a main portion of the organic EL display device.

FIG. 5 is a diagram explaining a specific example of the configuration of the main portion of the organic EL display device.

FIG. 6 is a diagram explaining an adjustment method for a neutral face illustrated in FIG. 4.

FIGS. 7A and 7B are diagrams explaining a main manufacturing process of the organic EL display device, and specifically explain a sequence of main manufacturing processes.

FIGS. 8A and 8B are diagrams explaining a main manufacturing process of the organic EL display device, and specifically explain a sequence of main manufacturing processes subsequently carried out after the processes illustrated in FIG. 7B.

FIGS. 9A and 9B are diagrams explaining a main manufacturing process of the organic EL display device, and specifically explain a sequence of main manufacturing processes subsequently carried out after the processes illustrated in FIG. 8B.

FIG. 10 is a diagram explaining a main manufacturing process of the organic EL display device, and specifically explains a sequence of main manufacturing processes subsequently carried out after the processes illustrated in FIG. 9B.

FIG. 11 is a diagram explaining the configuration of a main portion of an organic EL display device according to a second embodiment of the present invention.

FIG. 12 is a diagram explaining the configuration of a main portion of an organic EL display device according to a third embodiment of the present invention.

FIG. 13 is a diagram explaining the configuration of a main portion of an organic EL display device according to a fourth embodiment of the present invention.

### DESCRIPTION OF EMBODIMENTS

Hereinafter, preferred embodiments of an electroluminescence device according to the present invention will be stated with reference to the drawings. Note that the following description will be made by giving an example in which the present invention is applied to an organic EL display device. In addition, in each of the drawings, the dimensions of constituent elements are not precisely illustrated as the actual dimensions of the constituent elements and the dimensional proportions of each of the constituent elements.

### First Embodiment

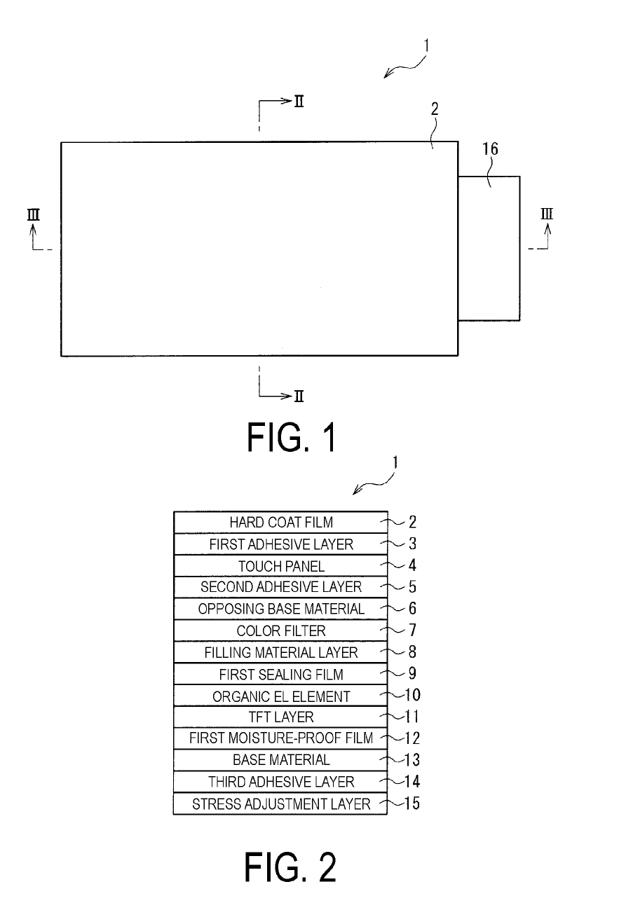

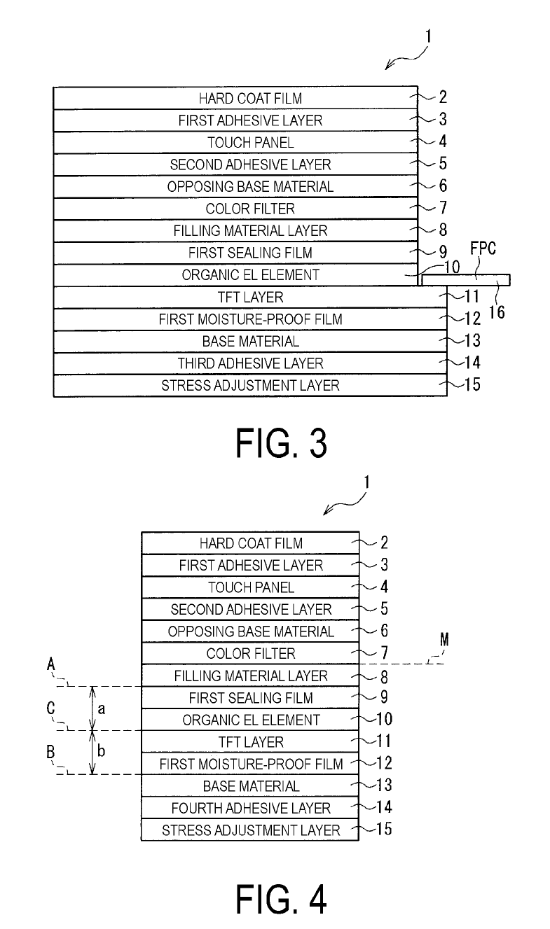

FIG. 1 is a plan view illustrating an organic EL display device according to a first embodiment of the present invention. FIG. 2 is a cross-sectional view taken along a II-II line in FIG. 1. FIG. 3 is a cross-sectional view taken along a III-III line in FIG. 1.

In FIG. 1, an organic EL display device 1 according to the present embodiment includes a hard coat film 2 provided on a display face side thereof, and a flexible printed circuit board 16 to connect a control unit (not illustrated) with an organic EL element and a thin film transistor to be explained later.

As illustrated in FIG. 2, the organic EL display device 1 according to the present embodiment includes: a flexible base material 13; and a first moisture-proof film 12, a TFT layer 11 and an organic EL element (electroluminescence element) 10 that are sequentially layered in that order on a surface on the display face side of the base material 13. Further, the organic EL display device 1 according to the present embodiment includes: a first sealing film 9 provided to cover the organic EL element 10; and a filling material layer 8, a color filter 7, an opposing base material 6, a second adhesive layer 5, a touch panel 4, a first adhesive layer 3 and the hard coat film 2 that are sequentially layered in that order on a surface on the display face side of the first sealing film 9. Furthermore, the organic EL display device 1 according to the present embodiment includes a third adhesive layer 14 and a stress adjustment layer 15 that are sequentially layered in that order on a surface of the base material 13 on the opposite side to the display surface.

The base material 13 functions as a support substrate to support the organic EL element 10. For this base material 13, a flexible material such as polyimide is used, for example. Accordingly, the organic EL display device 1 that can be repeatedly bent (bendable) can be constituted with ease in the present embodiment.

The first moisture-proof film 12 is provided on a surface on the organic EL element 10 side of the base material 13 between the base material 13 and the TFT layer 11, and is configured to prevent the permeation of moisture or the like from the base material 13 side to the TFT layer 11 and the organic EL element 10. An inorganic film such as silicon nitride (SiNx), silicon oxide, (SiOx), silicon oxynitride (SiON), or aluminum oxide (AlOx), for example, is used for the first moisture-proof film 12.

The TFT layer 11 includes a plurality of thin film transistors disposed corresponding to a plurality of pixels (not illustrated) provided in a matrix form inside the organic EL element 10, wiring line for driving the plurality of thin film transistors (not illustrated), and the like. Further, in the TFT layer 11, the wiring line is connected to the above-mentioned control unit via the flexible printed circuit board 16. Then, the thin film transistors are driven, on a pixel-by-pixel basis, to perform switching operation on the corresponding organic EL element pixel, whereby light emitting action is performed in the stated pixel.

The organic EL element 10 includes a first electrode connected to each of the plurality of thin film transistors, and an organic EL layer and a second electrode provided in sequence on the first electrode (not illustrated). In the organic EL element 10, the first electrode and the second electrode are connected to the control unit via the flexible printed circuit board 16, and the power is supplied from the control unit to the first electrode and second electrode. Further, the organic EL element 10 is configured in such a manner as to display information, such as characters or pictures, on the display face by performing light emitting action on a pixel-by-pixel basis.

As illustrated in FIG. 3, the organic EL element 10 and the TFT layer 11 are configured to have different dimensions from each other, and the flexible printed circuit board 16 is mounted on the TFT layer 11.

The first sealing film 9 is a sealing film configured to seal the organic EL element 10. For the first sealing film 9, a layered film of three-layer structure including an inorganic film, an organic film, and an inorganic film is used, for example. For the inorganic film, silicon nitride (SiNx), silicon oxide (SiOx), silicon oxynitride (SiON), aluminum oxide (AlOx) or the like, for example, is used. The stated inorganic film functions as a barrier layer configured to prevent the permeation of moisture, oxygen, or the like into the organic EL element 10. Further, for the organic film, organic silicon (organosilicon) such as polysiloxane or silicon oxycarbide, acrylate, polyurea, parylene, polyimide, polyamide, or the like is used, for example, and the stated organic film functions as a buffer layer configured to perform stress relaxation of the above-mentioned inorganic film, or the like.

It is sufficient for the first sealing film 9 to be a film configured to seal the organic EL element 10, and the first sealing film 9 may be configured to use a single-layer or multilayer sealing film using an inorganic film, for example.

For the filling material layer 8, a material in which a metal oxide such as aluminum hydroxide or calcium oxide, activated carbon, or the like is dispersed in a resin is used, for example.

The color filter 7 is disposed on the first sealing film 9 with the filling material layer 8 therebetween. RGB color filter units (not illustrated) are provided at the portions respectively opposing sub pixels Pr, Pg, and Pb of the RGB stated above, to improve light emission characteristics of the corresponding sub pixels Pr, Pg, and Pb. To be specific, provided is a function to enhance color purity of red by the R color filter appropriately absorbing part of light emitted from the R sub pixel Pr, for example.

The opposing base material 6 is provided opposing the base material 13 with the organic EL element 10 interposed therebetween. For this opposing base material 6, like the base material 13, a flexible material such as polyimide is used, for example, so that the bendable organic EL display device 1 is easily constituted.

Polyimide, a sensor for detection of a touch action of a user, and the like are used in the touch panel 4, for example. The touch panel 4 is attached on the base material 6 with the second adhesive layer 5 therebetween. In the organic EL display device 1 according to the present embodiment, a touch action of the user is detected by the touch panel 4, so that information display in response to the touch action can be carried out.

A film in which, for example, polyethylene terephthalate (PET) and acrylic resin as a base material are layered, is used for the hard coat film 2. The hard coat film 2 is disposed on the touch panel 4 with the first adhesive layer 3 therebetween. The organic EL display device 1 according to the present embodiment is configured in such a manner such that the display face (surface) thereof is protected by the hard coat film 2.

For the stress adjustment layer 15, a resin film of aramid, polyethylene naphthalate, polyethylene terephthalate, or the like can be used, for example. The Young's modulus can be further increased by using a carbon material such as graphite, graphene, carbon nanohorn, carbon nanofiber or carbon nanotube, or using a material in which the above-mentioned carbon material is dispersed in an organic resin. The stress adjustment layer 15 is disposed on the surface of the base material 13 on the opposite side to the organic EL element 10 side with the third adhesive layer 14 therebetween. The stress adjustment layer 15 is a layer for adjusting a neutral face of the organic EL display device 1. The organic EL display device 1 according to the present embodiment is configured such that the neutral face is positioned between an upper face of the first sealing film 9 and a lower face of the first moisture-proof film 12.

Further, in the organic EL display device 1 according to the present embodiment, the neutral face is set to an intermediate position between the upper face of the first sealing film 9 and the lower face of the first moisture-proof film 12, or to the vicinity of the intermediate position (preferably to the intermediate position).

The vicinity of the intermediate position refers to a position distanced from the intermediate position within a range of, for example, 0.1 to 3% of the total thickness of the organic EL display device 1 (the same is applied to second to fourth embodiments to be explained later).

A resin material of ultraviolet curing type, for example, is used for the first to third adhesive layers 3, 5, and 14. The first to third adhesive layers 3, 5, and 14 can have a drying function, a deoxidizing function, or the like using such a method in which a drying agent, a deoxidizing agent, or the like is mixed. This can prevent moisture, oxygen, or the like entering from the exterior and reaching the organic EL element 10 and damaging the organic EL element 10.

Next, using FIG. 4 to FIG. 6, the above-described neutral face in the organic EL display device 1 according to the present embodiment will be specifically described.

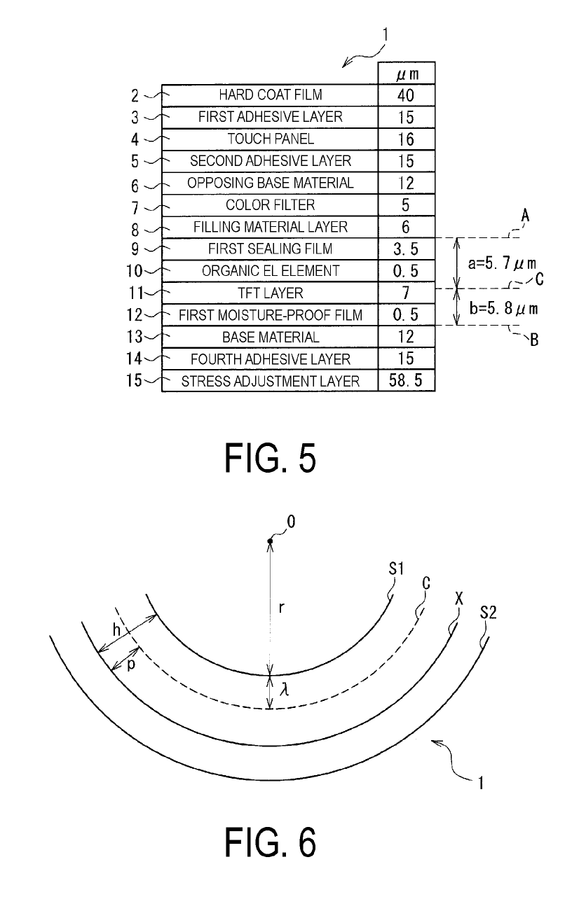

FIG. 4 is a diagram explaining the configuration of a main portion of the organic EL display device described above. FIG. 5 is a diagram explaining a specific example of the configuration of the main portion of the organic EL display device described above. FIG. 6 is a diagram explaining an adjustment method for the neutral face illustrated in FIG. 4.

As illustrated in FIG. 4, in the organic EL display device 1 according to the present embodiment, a neutral face C is set to an intermediate position between an upper face (in other words, a surface on the display face side) A of the first sealing film 9 and a lower face (in other words, a surface on the opposite side to the display face) B of the first moisture-proof film 12, or to the vicinity of the intermediate position. That is, in the organic EL display device 1 according to the present embodiment, a distance a from the upper face A of the first sealing film 9 to the neutral face C and a distance b from the neutral face C to the lower face B of the first moisture-proof film 12 are adjusted to have the same value or substantially have the same value.

Note that in FIG. 4, the center position in the thickness direction of the organic EL display device 1 according to the present embodiment is indicated by “M”, and the center position M is generally present at a position different from the position of the neutral face C.

To be specific, in the organic EL display device 1 according to the present embodiment, as illustrated in FIG. 5, thicknesses of the plurality of layers, that is, thicknesses of the hard coat film 2, the first adhesive layer 3, the touch panel 4, the second adhesive layer 5, the opposing base material 6, the color filter 7, the filling material layer 8, the first sealing film 9, the organic EL element 10, the TFT layer 11, the first moisture-proof film 12, the base material 13, the third adhesive layer 14, and the stress adjustment layer 15 are set to, for example, 40 μm, 15 μm, 16 μm, 15 μm, 12 μm, 5 μm, 6 μm, 3.5 μm, 0.5 μm, 7 μm, 0.5 μm, 12 μm, 15 μm, and 58.5 μm, respectively. In the organic EL display device 1 according to the present embodiment, the distance a is set to be 5.7 μm, the distance b is set to be 5.8 μm, and the neutral face C is positioned near an intermediate position between the upper face A of the first sealing film 9 and the lower face B of the first moisture-proof film 12.

Apart from the above description, the distance a and the distance b may have the same value, in other words, the neutral face C may be set to the intermediate position between the upper face A of the first sealing film 9 and the lower face B of the first moisture-proof film 12.

Here, the neutral face C in the organic EL display device 1 is a position where no distortion is generated when the organic EL display device 1 is bent. To be specific, as exemplified in FIG. 6, in the case where the organic EL display device 1 is bent with a radius of curvature r with respect to a bending center O, the neutral face C of the organic EL display device 1 is formed at a position indicated by a dotted line in the drawing in accordance with the Young's modulus and thickness of each layer included in the organic EL display device 1. At the neutral face C, because neither tension stress nor compression stress due to the bend is received, the distortion (expansion) becomes 0.

Each of the layers receives compression stress and is compressed in a bending direction in accordance with the Young's modulus of each layer on an inner side relative to the neutral face C (a range indicated by the neutral face C and a surface S1 on the innermost side in FIG. 6).

On the other hand, each of the layers receives tension stress and is expanded in the bending direction in accordance with the Young's modulus of each layer on an outer side relative to the neutral face C (a range indicated by the neutral face C and a surface S2 on the outermost side in FIG. 6).

A distortion rate Hr is determined by Equation (1) below where, as illustrated in FIG. 6, a distance from the surface S1 on the innermost side to the neutral face C is taken as λ, a distance from the neutral face C to a discretionary face X is taken as p, and the radius of curvature r is used. A distance h from the surface S1 on the innermost side to the discretionary face X is determined by adding the distance λ to the distance p.

Hr=p÷(r+λ) (1)

Then, in the organic EL display device 1 according to the present embodiment, Young's modulus and a thickness of each of the plurality of layers are set to make the distortion rate of each of the first sealing film 9 and the first moisture-proof film 12 become not greater than 1% in the case where the organic EL display device 1 is bent with the radius of curvature r being about 0.5 mm, where the radius of curvature r is a radius in the thickness direction of the organic EL display device 1 (in other words, from a value of 0.5 mm to a value within a predetermined range (e.g., about 0.5 mm)). By making (an absolute value of) each distortion rate of the first sealing film 9 and the first moisture-proof film 12 to be not greater than 1% as discussed above, the neutral face C is set to an intermediate position between the upper face A of the first sealing film 9 and the lower face B of the first moisture-proof film 12 or to the vicinity of the intermediate position, and further the occurrence of abnormal incidents such as a fracture in the first sealing film 9 or the first moisture-proof film 12 can be prevented (details of this will be explained later).

Furthermore, as discussed above, in the organic EL display device 1 according to the present embodiment, the neutral face C is set to the intermediate position between the upper face of the first sealing film 9 and the lower face of the first moisture-proof film 12, or to the vicinity of the intermediate position. Accordingly, in the organic EL display device 1 according to the present embodiment, the Young's modulus and thickness of each of the plurality of layers are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range (e.g., about 3.0 mm)).

Next, a calculation method for the neutral face C will be described in detail. As illustrated in FIG. 5, in a state in which a plurality of layers having the same width are layered in a depth direction, Young's modulus of each layer is taken as Eᵢ, a thickness thereof is taken as tᵢ, and a distance from the surface S₁ on the innermost side to each interface is taken as hᵢ. For example, the Young's modulus is E₁ and the thickness is t₁ that is equal to h₁ for the layer on the inner most side; for the second layer from the inner side, the Young's modulus is E₂ and the thickness is t₂ that is equal to a value obtained by subtracting h₁ from h₂.

In this state, the distance λ from the surface S1 on the inner side to the neutral face C is expressed by Equation (2) given below.

λ=Σ{Eᵢ×tᵢ×(hᵢ+hᵢ₋₁)}÷Σ(2×Eᵢ×tᵢ) (2)

In the present embodiment, as illustrated in FIG. 5, since the number of layers being layered is 14, Σ refers to a sum of a numerical sequence of i from 1 to 14. In the case of the number of layers being layered is n, the numerical sequence refers to the sum of n pieces. As is clear from Equation (2), by introducing a layer having a certain Young's modulus and thickness, the position of the neutral face C can be controlled. Further, a value obtained by dividing (hᵢ+hᵢ₋₁) of Equation (2) by two refers to the center position of the i-th layer. That is to say, Equation (2) also means that the position of the neutral face C is determined by performing weighting on a value of Young's modulus×thickness (Eᵢ×tᵢ) of each layer at the center position of the layer. Accordingly, in the layered structure as illustrated in FIG. 5, it can be understood that a layer closer to the surface is more capable of controlling the position of the neutral face C and can adjust the position of the neutral face C with the stress adjustment layer 15.

Next, an example of a result of simulation having been carried out by the inventors and the like of the present invention will be specifically described. In the following description, a simulation result (calculation result) will be exemplified in which the distortion rate of each of the first sealing film 9 and the first moisture-proof film 12 becomes not greater than 1% abnormal incidents such as a fracture in the first sealing film 9 or the first moisture-proof film 12 do not occur (the same is applied to the embodiments to be explained later). A film in which a first layer and a second layer were layered was applied to the hard coat film 2 (the same is applied to the embodiments to be explained later), where a material of the first layer (e.g., acrylic resin) was different from a material of the second layer (e.g., polyethylene terephthalate).

In the simulation, with a structure indicated in Table 1, an acceptable radius of curvature was calculated when the thickness of the stress adjustment layer 15 was changed. Table 2 shows a calculation result. In Table 2, a distance in a direction extending toward the hard coat film 2 side from the upper face of the first sealing film 9 or from the lower face of the first moisture-proof film 12 is represented with a positive sign, while a distance in a direction extending toward the stress adjustment layer 15 side from the upper face of the first sealing film 9 or from the lower face of the first moisture-proof film 12 is represented with a negative sign.

TABLE 1
Product of Present Embodiment

| | | Young's Modulus |
|---|---|---|
| | Thickness (μm) | (GPa) |
| Hard Coat Film, First Layer | 10 | 6.0 |
| Hard Coat Film, Second Layer | 30 | 4.0 |
| First Adhesive Layer | 15 | 3.0 |
| Touch Panel | 16 | 7.7 |
| Second Adhesive Layer | 15 | 3.0 |
| Opposing Base Material | 12 | 7.7 |
| Color Filter | 5 | 3.5 |
| Filling Material Layer | 6 | 3.0 |
| First Sealing Film | 3.5 | 80.0 |
| Organic EL Element | 0.5 | 0 |
| TFT Layer | 7 | 3.0 |
| First Moisture-proof Film | 0.5 | 240.0 |
| Base Material | 12 | 7.7 |
| Third Adhesive Layer | 15 | 3.0 |
| Stress Adjustment Layer | 0 to 80 | 8.0 |

TABLE 2

| | Distance from | Distance from | |
|---|---|---|---|
| | Upper Face of | Lower Face of | Acceptable |
| Stress | First Sealing Film to | First Moisture-proof | Radius of |
| Adjustment | Neutral Face | Film to Neutral Face | Curvature |
| Layer (μm) | (μm) | (μm) | (mm) |
| 0.0 | 22.5 | 34.0 | 3.4 |
| 10.0 | 16.8 | 28.3 | 2.7 |
| 20.0 | 12.2 | 23.7 | 2.3 |
| 30.0 | 7.6 | 16.1 | 1.8 |
| 40.0 | 3.0 | 14.5 | 1.4 |
| 50.0 | −1.7 | 9.8 | 0.9 |
| 58.5 | −5.7 | 5.8 | 0.5 |
| 70.0 | −11.2 | 0.3 | 1.0 |
| 80.0 | −15.9 | −4.4 | 1.5 |

As is clear from Table 2, it was understood that the acceptable radius of curvature was smallest in the product of the present embodiment in which the thickness of the stress adjustment layer 15 was 58.5 μm.

Further, it was confirmed that the stress adjustment layer 15 needed to be disposed when the organic EL display device 1 was bent with a radius of curvature of not greater than 3.4 mm.

As discussed above, with the use of the stress adjustment layer 15, by setting the neutral face C to an intermediate position between the upper face of the first sealing film 9 and the lower face of the first moisture-proof film 12 or to the vicinity of the intermediate position, it was confirmed that the radius of curvature was minimized without the occurrence of abnormal incidents such as a film fracture in each of the plurality of layers.

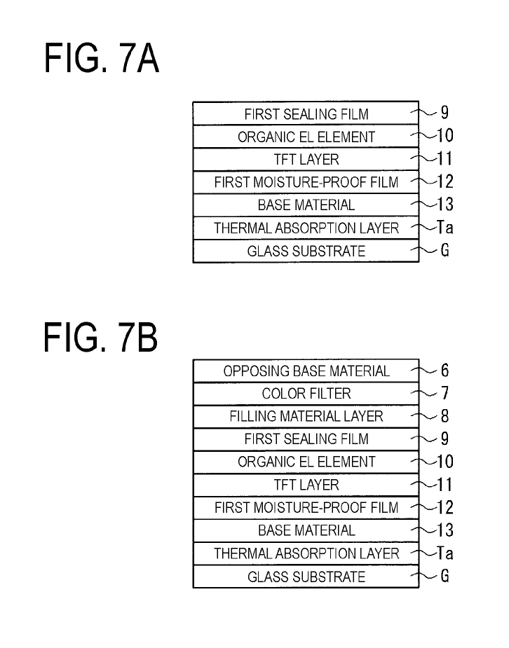

Next, with reference to FIG. 7A to FIG. 10, a manufacturing method for the organic EL display device 1 according to the present embodiment will be specifically described.

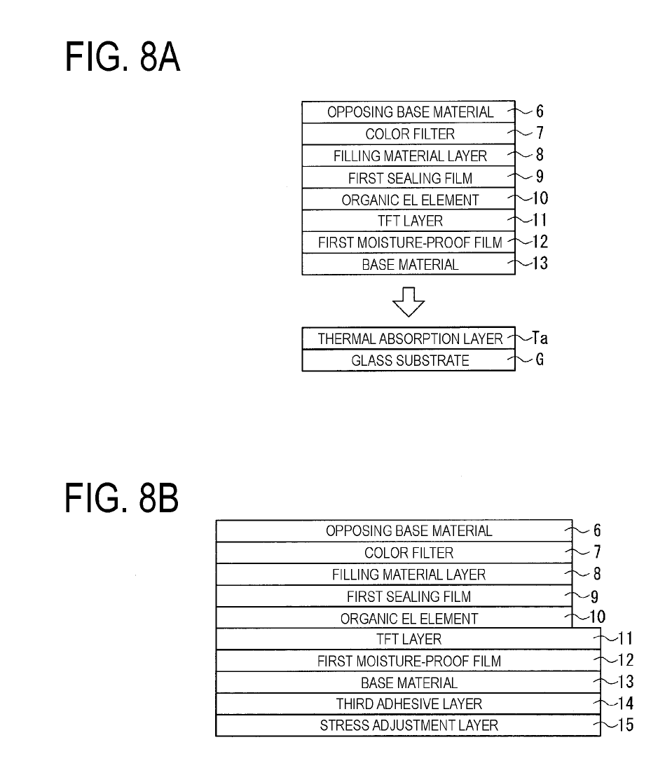

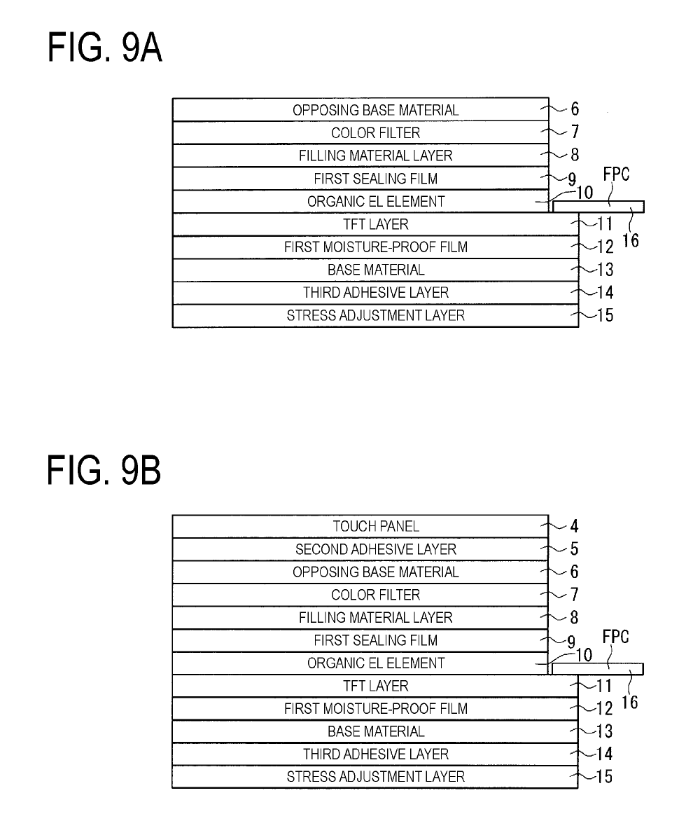

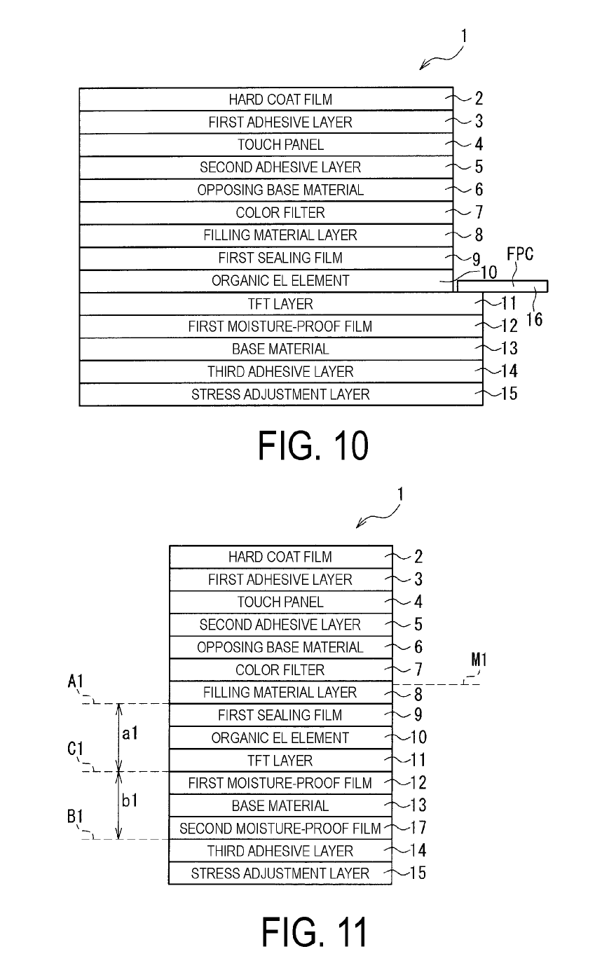

FIGS. 7A and 7B are diagrams explaining main manufacturing processes of the organic EL display device stated above, and specifically explain a sequence of main manufacturing processes. FIGS. 8A and 8B are diagrams explaining main manufacturing processes of the organic EL display device stated above, and specifically explain a sequence of main manufacturing processes subsequently carried out after the processes illustrated in FIG. 7B. FIGS. 9A and 9B are diagrams explaining main manufacturing processes of the organic EL display device stated above, and specifically explain a sequence of main manufacturing processes subsequently carried out after the processes illustrated in FIG. 8B. FIG. 10 is a diagram explaining main manufacturing processes of the organic EL display device stated above, and specifically explains a sequence of main manufacturing processes subsequently carried out after the processes illustrated in FIG. 9B.

As illustrated in FIG. 7A, on a glass substrate G, a thermal absorption layer Ta, the base material 13, the first moisture-proof film 12, the TFT layer 11, the organic EL element 10, and the first sealing film 9 are sequentially formed in that order. For the film formation of the first sealing film 9, a plasma CVD technique is used, for example.

Next, as illustrated in FIG. 7B, the color filter 7 and the opposing base material 6 are pasted to the first sealing film 9 using the filling material layer 8.

Subsequently, as illustrated in FIG. 8A, the thermal absorption layer Ta and the glass substrate G are separated from the base material 13 by radiating a laser beam to the thermal absorption layer Ta from the glass substrate G side. In this separation process, an excimer laser with a wavelength of 248 nm or 308 nm is used.

Next, as illustrated in FIG. 8B, the stress adjustment layer 15 is pasted to the base material 13 using the third adhesive layer 14.

Subsequently, as illustrated in FIG. 9A, the flexible printed circuit board 16 is attached on the TFT layer 11.

Next, as illustrated in FIG. 9B, the touch panel 4 is pasted to the opposing base material 6 using the second adhesive layer 5.

Subsequently, as illustrated in FIG. 10, the hard coat film 2 is pasted to the touch panel 4 using the first adhesive layer 3. With these processes, the organic EL display device 1 according to the present embodiment is completed.

In the organic EL display device 1 according to the present embodiment configured in this manner, the organic EL element 10 and the TFT layer 11 are sandwiched between the first sealing film 9 and the first moisture-proof film 12. Further, the stress adjustment layer 15 is provided for adjusting the neutral face C in the organic EL display device 1. The neutral face C is positioned between the upper face of the first sealing film 9 and the lower face of the first moisture-proof film 12. Thus, in the present embodiment, unlike the above-described known example, the occurrence of abnormal incidents such as a fracture in the first sealing film 9 or the first moisture-proof film 12 can be prevented even in the case where the organic EL display device 1 is bent. As a result, in the present embodiment, the organic EL display device 1 excellent in reliability that is capable of preventing the deterioration of the organic EL element 10 can be constituted.

Further, in the present embodiment, the neutral face C is set to the intermediate position between the upper face of the first sealing film 9 and the lower face of the first moisture-proof film 12, or to the vicinity of the intermediate position. Thus, in the present embodiment, the occurrence of abnormal incidents such as a fracture in the first sealing film 9 or the first moisture-proof film 12 can be prevented with certainty even in the case where the organic EL display device 1 is bent. As a result, in the present embodiment, the organic EL display device 1 more excellent in reliability that is capable of surely preventing the deterioration of the organic EL element 10 can be easily constituted.

In the present embodiment, the Young's modulus and thickness of each of the plurality of layers included in the organic EL display device 1 are set to make the distortion rate of each of the first sealing film 9 and the first moisture-proof film 12 become not greater than 1% in the case where the organic EL display device 1 is bent with the radius of curvature being about 0.5 mm. Thus, in the present embodiment, the occurrence of abnormal incidents such as a fracture in the first sealing film 9 or the first moisture-proof film 12 can be prevented with more certainty even in the case where the organic EL display device 1 is bent with the radius of curvature being about 0.5 mm.

Further, in the present embodiment, the Young's modulus and thickness of each of the plurality of layers included in the organic EL display device 1 are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range). Thus, in the present embodiment, the occurrence of abnormal incidents such as a fracture in the hard coat film 2 or the stress adjustment layer 15 can be prevented with more certainty even in the case where the organic EL display device 1 is bent with the radius of curvature being about 3.0 mm.

Furthermore, in the present embodiment, the hard coat film 2 is formed of a hard coat layer and a base material layered together, or formed of only a hard coat layer. Thus, the surface of the organic EL display device 1 can be protected with certainty, thereby making it possible to protect the organic EL element 10 with ease.

### Second Embodiment

FIG. 11 is a diagram explaining the configuration of a main portion of an organic EL display device according to a second embodiment of the present invention.

In FIG. 11, a major different point between the present embodiment and the first embodiment is such that the present embodiment includes a second moisture-proof film provided on a surface of the base material on the opposite side to the organic EL element, and a neutral face is positioned between the upper face of the first sealing film and a lower face of the second moisture-proof film. Note that elements common to those in the first embodiment are denoted by the same reference signs, and duplicated description thereof will be omitted.

More specifically, as illustrated in FIG. 11, in the organic EL display device 1 according to the present embodiment, a second moisture-proof film 17 is provided on a surface of the base material 13 on the opposite side to the organic EL element 10 side. An inorganic film such as silicon nitride (SiNx), silicon oxide (SiOx), silicon oxynitride (SiON), or aluminum oxide (AlOx), for example, is used for the second moisture-proof film 17 like the first moisture-proof film 12. The stress adjustment layer 15 is disposed on the second moisture-proof film 17 with the third adhesive layer 14 interposed therebetween.

The organic EL display device 1 according to the present embodiment is configured such that a neutral face C1 is positioned between an upper face of the first sealing film 9 and a lower face of the second moisture-proof film 17. To be specific, in the organic EL display device 1 according to the present embodiment, the neutral face C1 is set to an intermediate position between an upper face (in other words, a surface on the display face side) A1 of the first sealing film 9 and a lower face (in other words, a surface on the opposite side to the display face) B1 of the second moisture-proof film 17, or to the vicinity of the intermediate position (preferably to the intermediate position). That is, in the organic EL display device 1 according to the present embodiment, a distance a1 from the upper face A1 of the first sealing film 9 to the neutral face C1 and a distance b1 from the neutral face C1 to the lower face B1 of the second moisture-proof film 17 are adjusted to have the same value or substantially have the same value.

Note that in FIG. 11, the center position in the thickness direction of the organic EL display device 1 according to the present embodiment is indicated by “M1”, and the center position M1 is generally present at a position different from the position of the neutral face C1.

Then, in the organic EL display device 1 according to the present embodiment, the Young's modulus and thickness of each of the plurality of layers are set to make the distortion rate of each of the first sealing film 9, the first moisture-proof film 12, and the second moisture-proof film 17 become not greater than 1% in the case where the organic EL display device 1 is bent with the radius of curvature r being about 1.1 mm, where the radius of curvature r is a radius in the thickness direction of the organic EL display device 1 (in other words, from a value of 1.1 mm to a value within a predetermined range (e.g., about 1.1 mm)). By making (an absolute value of) each distortion rate of the first sealing film 9, the first moisture-proof film 12, and the second moisture-proof film 17 to be not greater than 1% as discussed above, the neutral face C1 is set to an intermediate position between the upper face A1 of the first sealing film 9 and the lower face B1 of the second moisture-proof film 17 or to the vicinity of the intermediate position, and further the occurrence of abnormal incidents such as a fracture in the first sealing film 9, the first moisture-proof film 12, or the second moisture-proof film 17 can be prevented.

Further, in the organic EL display device 1 according to the present embodiment, as described above, the neutral face C1 is set to the intermediate position between the upper face of the first sealing film 9 and the lower face of the second moisture-proof film 17, or to the vicinity of the intermediate position. Accordingly, in the organic EL display device 1 according to the present embodiment, the Young's modulus and thickness of each of the plurality of layers are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range (e.g., about 3.0 mm)).

Next, an example of a result of simulation having been carried out by the inventors and the like of the present invention will be specifically described. In the following description, a simulation result (calculation result) will be exemplified in which the distortion rate of each of the first sealing film 9, the first moisture-proof film 12, and the second moisture-proof film 17 becomes not greater than 1% and abnormal incidents such as a fracture in the first sealing film 9, the first moisture-proof film 12, or the second moisture-proof film 17 do not occur.

In the simulation, with a structure indicated in Table 3, an acceptable radius of curvature was calculated when the thickness of the stress adjustment layer 15 was changed. Table 4 shows a calculation result. In Table 4, a distance in a direction extending toward the hard coat film 2 side from the upper face of the first sealing film 9 or from the lower face of the second moisture-proof film 17 is represented with a positive sign, while a distance in a direction extending toward the stress adjustment layer 15 side from the upper face of the first sealing film 9 or from the lower face of the second moisture-proof film 17 is represented with a negative sign.

TABLE 3
Product of Present Embodiment

| | | Young's Modulus |
|---|---|---|
| | Thickness (μm) | (GPa) |
| Hard Coat Film, First Layer | 10 | 6.0 |
| Hard Coat Film, Second Layer | 30 | 4.0 |
| First Adhesive Layer | 15 | 3.0 |
| Touch Panel | 16 | 7.7 |
| Second Adhesive Layer | 15 | 3.0 |
| Opposing Base Material | 12 | 7.7 |
| Color Filter | 5 | 3.5 |
| Filling Material Layer | 6 | 3.0 |
| First Sealing Film | 3.5 | 80.0 |
| Organic EL Element | 0.5 | 0 |
| TFT Layer | 7 | 3.0 |
| First Moisture-proof Film | 0.5 | 240.0 |
| Base Material | 12 | 7.7 |
| Second Moisture-proof Film | 0.5 | 240.0 |
| Third Adhesive Layer | 15 | 3.0 |
| Stress Adjustment Layer | 0 to 90 | 8.0 |

TABLE 4

| | Distance from | Distance from | |
|---|---|---|---|
| | Upper Face of | Lower Face of | Acceptable |
| Stress | First Sealing Film | Second Moisture-proof | Radius |
| Adjustment | to Neutral Face | Film to Neutral Face | of Curvature |
| Layer (μm) | (μm) | (μm) | (mm) |
| 0.0 | 16.7 | 40.7 | 4.0 |
| 10.0 | 12.9 | 36.9 | 3.6 |
| 20.0 | 9.0 | 33.0 | 3.2 |
| 30.0 | 4.9 | 28.9 | 2.8 |
| 40.0 | 0.7 | 24.7 | 2.4 |
| 50.0 | −3.5 | 20.5 | 2.0 |
| 60.0 | −7.8 | 16.2 | 1.6 |
| 69.5 | −12.0 | 12.0 | 1.1 |
| 80.0 | −16.6 | 7.4 | 1.6 |
| 90.0 | −21.1 | 2.9 | 2.0 |

As is clear from Table 4, it was understood that the acceptable radius of curvature was smallest in the product of the present embodiment in which the thickness of the stress adjustment layer 15 was 69.5 μm.

Further, it was confirmed that the stress adjustment layer 15 needed to be disposed when the organic EL display device 1 was bent with a radius of curvature of not greater than 4.0 mm.

With the configuration stated above, the present embodiment can achieve operation and effect similar to those of the first embodiment.

In the present embodiment, the second moisture-proof film 17 is provided on the surface of the base material 13 on the opposite side to the organic EL element 10 side. The neutral face C1 is positioned between the upper face of the first sealing film 9 and the lower face of the second moisture-proof film 17. Thus, in the present embodiment, the occurrence of abnormal incidents such as a fracture in the first sealing film 9, the first moisture-proof film 12, or the second moisture-proof film 17 can be prevented even in the case where the organic EL display device 1 is bent. In addition, the second moisture-proof film 17 makes it possible to prevent the permeation of moisture or the like from the opposite side of the base material 13 relative to the organic EL element 10 side, whereby the organic EL display device 1 more excellent in reliability can be easily constituted.

Further, in the present embodiment, the neutral face C1 is set to the intermediate position between the upper face of the first sealing film 9 and the lower face of the second moisture-proof film 17, or to the vicinity of the intermediate position. Thus, in the present embodiment, the occurrence of abnormal incidents such as a fracture in the first sealing film 9, the first moisture-proof film 12, or the second moisture-proof film 17 can be prevented with certainty even in the case where the organic EL display device 1 is bent. As a result, in the present embodiment, the organic EL display device 1 more excellent in reliability that is capable of surely preventing the deterioration of the organic EL element 10 can be easily constituted.

In the present embodiment, the Young's modulus and thickness of each of the plurality of layers included in the organic EL display device 1 are set to make the distortion rate of each of the first sealing film 9, the first moisture-proof film 12, and the second moisture-proof film 17 become not greater than 1% in the case where the organic EL display device 1 is bent with the radius of curvature being about 1.1 mm. Thus, in the present embodiment, the occurrence of abnormal incidents such as a fracture in the first sealing film 9, the first moisture-proof film 12, or the second moisture-proof film 17 can be prevented with more certainty even in the case where the organic EL display device 1 is bent with the radius of curvature being about 1.1 mm.

Further, in the present embodiment, the Young's modulus and thickness of each of the plurality of layers included in the organic EL display device 1 are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range). Thus, in the present embodiment, the occurrence of abnormal incidents such as a fracture in the hard coat film 2 or the stress adjustment layer 15 can be prevented with more certainty even in the case where the organic EL display device 1 is bent with the radius of curvature being about 3.0 mm.

### Third Embodiment

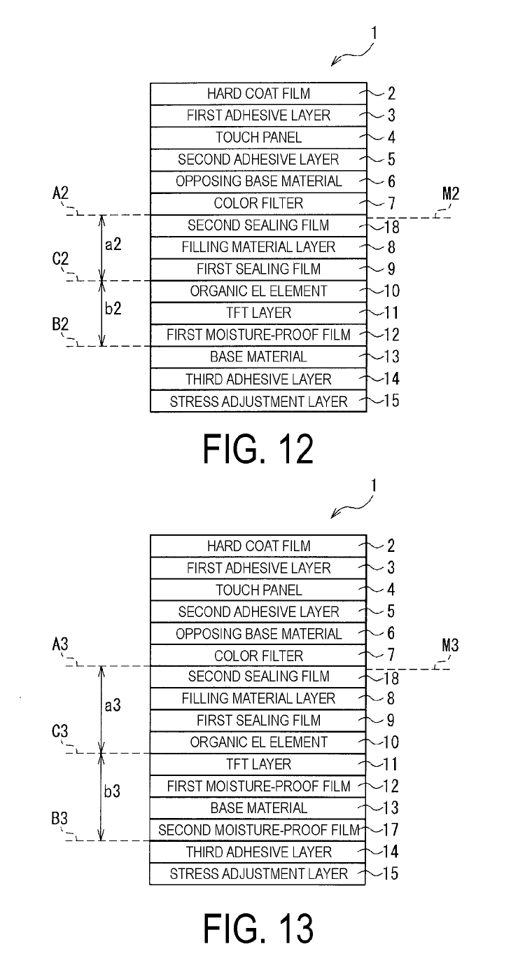

FIG. 12 is a diagram explaining the configuration of a main portion of an organic EL display device according to a third embodiment of the present invention.

In FIG. 12, a major different point between the present embodiment and the first embodiment is such that the present embodiment includes a second sealing film provided in the upper portion of the first sealing film, and a neutral face is positioned between the first moisture-proof film and the second sealing film. Note that elements common to those in the first embodiment are denoted by the same reference signs, and duplicated description thereof will be omitted.

More specifically, as illustrated in FIG. 12, in the organic EL display device 1 according to the present embodiment, a second sealing film 18 is provided on the first sealing film 9 with the filling material layer 8 interposed therebetween. For the second sealing film 18, like the first sealing film 9, a film in which an inorganic film and an organic film are layered is used, for example.

The organic EL display device 1 according to the present embodiment is configured such that a neutral face C2 is positioned between an upper face of the second sealing film 18 and a lower face of the first moisture-proof film 12. To be specific, in the organic EL display device 1 according to the present embodiment, the neutral face C2 is set to an intermediate position between an upper face (in other words, a surface on the display face side stated above) A2 of the second sealing film 18 and a lower face (in other words, a surface on the opposite side to the display face stated above) B2 of the first moisture-proof film 12, or to the vicinity of the intermediate position (preferably to the intermediate position). That is, in the organic EL display device 1 according to the present embodiment, a distance a2 from the upper face A2 of the second sealing film 18 to the neutral face C2 and a distance b2 from the neutral face C2 to the lower face B2 of the first moisture-proof film 12 are adjusted to have the same value or substantially have the same value.

Note that in FIG. 12, the center position in the thickness direction of the organic EL display device 1 according to the present embodiment is indicated by “M2”, and the center position M2 is generally present at a position different from the position of the neutral face C2.

Further, in the organic EL display device 1 according to the present embodiment, the Young's modulus and thickness of each of the plurality of layers are set to make the distortion rate of each of the second sealing film 18, the first sealing film 9, and the first moisture-proof film 12 become not greater than 1% in the case where the organic EL display device 1 is bent with the radius of curvature r being about 0.8 mm, where the radius of curvature r is a radius in the thickness direction of the organic EL display device 1 (in other words, from a value of 0.8 mm to a value within a predetermined range (e.g., about 0.8 mm)). By making (an absolute value of) each distortion rate of the second sealing film 18, the first sealing film 9, and the first moisture-proof film 12 to be not greater than 1% as discussed above, the neutral face C2 is set to the intermediate position between the upper face A2 of the second sealing film 18 and the lower face B2 of the first moisture-proof film 12 or to the vicinity of the intermediate position, and further the occurrence of abnormal incidents such as a fracture in the second sealing film 18, the first sealing film 9, or the first moisture-proof film 12 can be prevented.

Furthermore, in the organic EL display device 1 according to the present embodiment, the neutral face C2 is set to the intermediate position between the upper face of the second sealing film 18 and the lower face of the first moisture-proof film 12, or to the vicinity of the intermediate position, as discussed above. Accordingly, in the organic EL display device 1 according to the present embodiment, the Young's modulus and thickness of each of the plurality of layers are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range (e.g., about 3.0 mm)).

Next, an example of a result of simulation having been carried out by the inventors and the like of the present invention will be specifically described. In the following description, a simulation result (calculation result) will be exemplified in which the distortion rate of each of the second sealing film 18, the first sealing film 9, and the first moisture-proof film 12 becomes not greater than 1% and abnormal incidents such as a fracture in the second sealing film 18, the first sealing film 9, or the first moisture-proof film 12 do not occur.

In the simulation, with a structure indicated in Table 5, an acceptable radius of curvature was calculated when the thickness of the stress adjustment layer 15 was changed. Table 6 shows a calculation result. In Table 6, a distance in a direction extending toward the hard coat film 2 side from the upper face of the second sealing film 18 or from the lower face of the first moisture-proof film 12 is represented with a positive sign, while a distance in a direction extending toward the stress adjustment layer 15 side from the upper face of the second sealing film 18 or from the lower face of the first moisture-proof film 12 is represented with a negative sign.

TABLE 5
Product of Present Embodiment

| | | Young's Modulus |
|---|---|---|
| | Thickness (μm) | (GPa) |
| Hard Coat Film, First Layer | 10 | 6.0 |
| Hard Coat Film, Second Layer | 30 | 4.0 |
| First Adhesive Layer | 15 | 3.0 |
| Touch Panel | 16 | 7.7 |
| Second Adhesive Layer | 15 | 3.0 |
| Opposing Base Material | 12 | 7.7 |
| Color Filter | 5 | 3.5 |
| Second Sealing Film | 0.5 | 80.0 |
| Filling Material Layer | 6 | 3.0 |
| First Sealing Film | 3.5 | 80.0 |
| Organic EL Element | 0.5 | 0 |
| TFT Layer | 7 | 3.0 |
| First Moisture-proof Film | 0.5 | 240.0 |
| Base Material | 12 | 7.7 |
| Third Adhesive Layer | 15 | 3.0 |
| Stress Adjustment Layer | 0 to 70 | 8.0 |

TABLE 6

| | Distance from | Distance from | |
|---|---|---|---|
| | Upper Face of | Lower Face of | Acceptable |
| Stress | Second Sealing Film | First Moisture-proof | Radius |
| Adjustment | to Neutral Face | Film to Neutral Face | of Curvature |
| Layer (μm) | (μm) | (μm) | (mm) |
| 0.0 | 14.4 | 32.4 | 3.2 |
| 10.0 | 10.1 | 28.1 | 2.8 |
| 20.0 | 5.7 | 23.7 | 2.3 |
| 30.0 | 1.3 | 19.3 | 1.9 |
| 40.0 | −3.3 | 14.7 | 1.4 |
| 50.0 | −7.8 | 10.2 | 1.0 |
| 52.5 | −9.0 | 9.0 | 0.8 |
| 60.0 | −12.5 | 5.5 | 1.2 |
| 70.0 | −17.1 | 0.9 | 1.6 |

As is clear from Table 6, it was understood that the acceptable radius of curvature was smallest in the product of the present embodiment in which the thickness of the stress adjustment layer 15 was 52.5 μm.

Further, it was confirmed that the stress adjustment layer 15 needed to be disposed when the organic EL display device 1 was bent with a radius of curvature of not greater than 3.2 mm.

With the configuration stated above, the present embodiment can achieve operation and effect similar to those of the first embodiment.

In the present embodiment, the second sealing film 18 is provided in the upper portion of the first sealing film 9 to seal the organic EL element 10. In addition, the neutral face C2 is positioned between the upper face of the second sealing film 18 and the lower face of the first moisture-proof film 12. Thus, in the present embodiment, the occurrence of abnormal incidents such as a fracture in the second sealing film 18, the first sealing film 9, or the first moisture-proof film 12 can be prevented even in the case where the organic EL display device 1 is bent. Further, the second sealing film 18 makes it possible to prevent the permeation of moisture or the like from the organic EL element 10 side of the base material 13, whereby the organic EL display device 1 more excellent in reliability can be easily constituted.

Furthermore, in the present embodiment, the neutral face C2 is set to the intermediate position between the upper face of the second sealing film 18 and the lower face of the first moisture-proof film 12, or to the vicinity of the intermediate position. Thus, in the present embodiment, the occurrence of abnormal incidents such as a fracture in the second sealing film 18, the first sealing film 9, or the first moisture-proof film 12 can be prevented with certainty even in the case where the organic EL display device 1 is bent. As a result, in the present embodiment, the organic EL display device 1 more excellent in reliability that is capable of surely preventing the deterioration of the organic EL element 10 can be easily constituted.

In the present embodiment, the Young's modulus and thickness of each of the plurality of layers included in the organic EL display device 1 are set to make the distortion rate of each of the second sealing film 18, the first sealing film 9, and the first moisture-proof film 12 become not greater than 1% in the case where the organic EL display device 1 is bent with the radius of curvature being about 0.8 mm. Thus, in the present embodiment, the occurrence of abnormal incidents such as a fracture in the second sealing film 18, the first sealing film 9, or the first moisture-proof film 12 can be prevented with more certainty even in the case where the organic EL display device 1 is bent with the radius of curvature being about 0.8 mm.

Further, in the present embodiment, the Young's modulus and thickness of each of the plurality of layers included in the organic EL display device 1 are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range). With this, in the present embodiment, the occurrence of abnormal incidents such as a fracture in the hard coat film 2 or the stress adjustment layer 15 can be prevented with more certainty even in the case where the organic EL display device 1 is bent with the radius of curvature being about 3.0 mm.

### Fourth Embodiment

FIG. 13 is a diagram explaining the configuration of a main portion of an organic EL display device according to a fourth embodiment of the present invention.

In FIG. 13, a major different point between the present embodiment and the first embodiment is such that the present embodiment includes the second moisture-proof film provided on a surface of the base material on the opposite side to the organic EL element side and the second sealing film provided in the upper portion of the first sealing film, and a neutral face is positioned between the second moisture-proof film and the second sealing film. Note that elements common to those in the first embodiment are denoted by the same reference signs, and duplicated description thereof will be omitted.

More specifically, as illustrated in FIG. 13, in the organic EL display device 1 according to the present embodiment, the second moisture-proof film 17 is provided on a surface of the base material 13 on the opposite side to the organic EL element 10 side in the same manner as that in the second embodiment. Further, in the organic EL display device 1 according to the present embodiment, the second sealing film 18 is provided on the first sealing film 9 with the filling material layer 8 interposed therebetween in the same manner as that in the third embodiment.

The organic EL display device 1 according to the present embodiment is configured such that a neutral face C3 is positioned between an upper face of the second sealing film 18 and a lower face of the second moisture-proof film 17. To be specific, in the organic EL display device 1 according to the present embodiment, the neutral face C3 is set to an intermediate position between an upper face (in other words, a surface on the display face side) A3 of the second sealing film 18 and a lower face (in other words, a surface on the opposite side to the display face) B3 of the second moisture-proof film 17, or to the vicinity of the intermediate position (preferably to the intermediate position). That is, in the organic EL display device 1 according to the present embodiment, a distance a3 from the upper face A3 of the second sealing film 18 to the neutral face C3 and a distance b3 from the neutral face C3 to the lower face B3 of the second moisture-proof film 17 are adjusted to have the same value or substantially have the same value.

Note that in FIG. 13, the center position in the thickness direction of the organic EL display device 1 according to the present embodiment is indicated by “M3”, and the center position M3 is generally present at a position different from the position of the neutral face C3.

Then, in the organic EL display device 1 according to the present embodiment, Young's modulus and a thickness of each of the plurality of layers are set to make the distortion rate of each of the second sealing film 18, the first sealing film 9, the first moisture-proof film 12, and the second moisture-proof film 17 become not greater than 1% in the case where the organic EL display device 1 is bent with the radius of curvature r being about 1.5 mm, where the radius of curvature r is a radius in the thickness direction of the organic EL display device 1 (in other words, from a value of 1.5 mm to a value within a predetermined range (e.g., about 1.5 mm)). By making (an absolute value of) each distortion rate of the second sealing film 18, the first sealing film 9, the first moisture-proof film 12, and the second moisture-proof film 17 to be not greater than 1% as discussed above, the neutral face C3 is set to the intermediate position between the upper face A3 of the second sealing film 18 and the lower face B3 of the second moisture-proof film 17 or to the vicinity of the intermediate position, and further the occurrence of abnormal incidents such as a fracture in the second sealing film 18, the first sealing film 9, the first moisture-proof film 12, or the second moisture-proof film 17 can be prevented.

Furthermore, in the organic EL display device 1 according to the present embodiment, the neutral face C3 is set to the intermediate position between the upper face of the second sealing film 18 and the lower face of the second moisture-proof film 17, or to the vicinity of the intermediate position, as discussed above. Accordingly, in the organic EL display device 1 according to the present embodiment, the Young's modulus and thickness of each of the plurality of layers are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range (e.g., about 3.0 mm)).

Next, an example of a result of simulation having been carried out by the inventors and the like of the present invention will be specifically described. In the following description, a simulation result (calculation result) will be exemplified in which the distortion rate of each of the second sealing film 18, the first sealing film 9, the first moisture-proof film 12, and the second moisture-proof film 17 becomes not greater than 1% and abnormal incidents such as a fracture in the second sealing film 18, the first sealing film 9, the first moisture-proof film 12, or the second moisture-proof film 17 do not occur.

In the simulation, with a structure indicated in Table 7, an acceptable radius of curvature was calculated when the thickness of the stress adjustment layer 15 was changed. Table 8 shows a calculation result. In Table 8, a distance in a direction extending toward the hard coat film 2 side from the upper face of the second sealing film 18 or from the lower face of the second moisture-proof film 17 is represented with a positive sign, while a distance in a direction extending toward the stress adjustment layer 15 side from the upper face of the second sealing film 18 or from the lower face of the second moisture-proof film 17 is represented with a negative sign.

TABLE 7
Product of Present Embodiment

| | | Young's Modulus |
|---|---|---|
| | Thickness (μm) | (GPa) |
| Hard Coat Film, First Layer | 10 | 6.0 |
| Hard Coat Film, Second Layer | 30 | 4.0 |
| First Adhesive Layer | 15 | 3.0 |
| Touch Panel | 16 | 7.7 |
| Second Adhesive Layer | 15 | 3.0 |
| Opposing Base Material | 12 | 7.7 |
| Color Filter | 5 | 3.5 |
| Second Sealing Film | 0.5 | 80.0 |
| Filling Material Layer | 6 | 3.0 |
| First Sealing Film | 3.5 | 80.0 |
| Organic EL Element | 0.5 | 0 |
| TFT Layer | 7 | 3.0 |
| First Moisture-proof Film | 0.5 | 240.0 |
| Base Material | 12 | 7.7 |
| Second Moisture-proof Film | 0.5 | 240.0 |
| Third Adhesive Layer | 15 | 3.0 |
| Stress Adjustment Layer | 0 to 80 | 8.0 |

TABLE 8

| | Distance from | Distance from | |
|---|---|---|---|
| | Upper Face of | Lower Face of | Acceptable |
| Stress | Second Sealing Film | Second Moisture-proof | Radius |
| Adjustment | to Neutral Face | Film to Neutral Face | of Curvature |
| Layer (μm) | (μm) | (μm) | (mm) |
| 0.0 | 10.1 | 40.6 | 4.0 |
| 10.0 | 6.4 | 36.9 | 3.6 |
| 20.0 | 2.6 | 33.1 | 3.3 |
| 30.0 | −1.4 | 29.1 | 2.9 |
| 40.0 | −5.5 | 25.0 | 2.4 |
| 50.0 | −9.6 | 20.9 | 2.0 |
| 60.0 | −13.9 | 16.6 | 1.6 |
| 63.0 | −15.1 | 15.4 | 1.5 |
| 70.0 | −18.2 | 12.3 | 1.7 |
| 80.0 | −22.5 | 8.0 | 2.2 |

As is clear from Table 8, it was understood that the acceptable radius of curvature was smallest in the product of the present embodiment in which the thickness of the stress adjustment layer 15 was 63.0 μm.

Further, it was confirmed that the stress adjustment layer 15 needed to be disposed when the organic EL display device 1 was bent with a radius of curvature of not greater than 4.0 mm.

With the configuration stated above, the present embodiment can achieve operation and effect similar to those of the first embodiment.

In the present embodiment, the second moisture-proof film 17 is provided on the surface of the base material 13 on the opposite side to the organic EL element 10 side, and the second sealing film 18 is provided in the upper portion of the first sealing film 9. In addition, the neutral face C3 is positioned between the upper face of the second sealing film 18 and the lower face of the second moisture-proof film 17. Thus, in the present embodiment, the occurrence of abnormal incidents such as a fracture in the second sealing film 18, the first sealing film 9, the first moisture-proof film 12, or the second moisture-proof film 17 can be prevented even in the case where the organic EL display device 1 is bent. In addition, the second sealing film 18 and the second moisture-proof film 17 make it possible to prevent the permeation of moisture or the like from the opposite side of the base material 13 relative to the organic EL element 10 side and from the organic EL element 10 side of the base material 13, whereby the organic EL display device 1 more excellent in reliability can be easily constituted.

Furthermore, in the present embodiment, the neutral face C3 is set to the intermediate position between the upper face of the second sealing film 18 and the lower face of the second moisture-proof film 17, or to the vicinity of the intermediate position. Thus, in the present embodiment, the occurrence of abnormal incidents such as a fracture in the second sealing film 18, the first sealing film 9, the first moisture-proof film 12, or the second moisture-proof film 17 can be prevented with certainty even in the case where the organic EL display device 1 is bent. As a result, in the present embodiment, the organic EL display device 1 more excellent in reliability that is capable of surely preventing the deterioration of the organic EL element 10 can be easily constituted.

In the present embodiment, the Young's modulus and thickness of each of the plurality of layers included in the organic EL display device 1 are set to make the distortion rate of each of the second sealing film 18, the first sealing film 9, the first moisture-proof film 12, and the second moisture-proof film 17 become not greater than 1% in the case where the organic EL display device 1 is bent with the radius of curvature being about 1.5 mm. Thus, in the present embodiment, the occurrence of abnormal incidents such as a fracture in the second sealing film 18, the first sealing film 9, the first moisture-proof film 12, or the second moisture-proof film 17 can be prevented with more certainty even in the case where the organic EL display device 1 is bent with the radius of curvature being about 1.5 mm.

Further, in the present embodiment, the Young's modulus and thickness of each of the plurality of layers included in the organic EL display device 1 are set to make the distortion rate of each of the hard coat film 2 and the stress adjustment layer 15 become not greater than 4% in the case where the organic EL display device 1 is bent with the radius of curvature r being about 3.0 mm, where the radius of curvature r is a radius in the thickness direction of the organic EL display device 1 (in other words, from a value of 3.0 mm to a value within a predetermined range). With this, in the present embodiment, the occurrence of abnormal incidents such as a fracture in the hard coat film 2 or the stress adjustment layer 15 can be prevented with more certainty even in the case where the organic EL display device 1 is bent with the radius of curvature being about 3.0 mm.

Note that all the embodiments stated above are given only as examples, and are not given for limitation. The technical scope of the present invention is defined by Claims, and all modifications made within the scope equivalent to the configuration stated in Claims are included in the technical scope of the present invention.

For example, in the description above, description has been made of a case where an organic EL element is used as an electroluminescence element. However, the present invention is not limited to this. For example, it may be possible to use an inorganic EL element including an inorganic compound.

In addition, in the description above, description has been made on an organic EL display device including a touch panel. However, the present invention is not limited to this. For example, the present invention can also be applied to a display device not including a touch panel, or to an illumination device such as a backlight device.

Although, in the description of the above embodiments, the configuration in which the opposing base material, the color filter, and the filling material layer are provided has been explained, the present invention is not limited thereto. For example, the present invention may be applied to a configuration in which at least one layering of the opposing base material, the color filter, and the filling material layer is omitted. In the case where, as described above, at least one of the opposing base material, the color filter, and the filling material layer is not disposed, it is needless to say that the position of the neutral face is set in consideration of Young's modulus and a thickness of each of the plurality of layers included in the electroluminescence device as in the cases of the above-discussed embodiments.

Although a circular polarizing plate is not provided in the description of the above embodiments, a circular polarizing plate may be additionally provided on the touch panel, for example, in order to enhance the display quality by suppressing external light reflection on the surface. In the case of the circular polarizing plate being added, it goes without saying that the neutral face is set in consideration of the Young's modulus and thickness thereof as in the cases of the above-discussed embodiments.

Although, in the description of the above embodiments, the configuration in which the stress adjustment layer is provided on the opposite side of the base material to the organic EL element (electroluminescence element) side is explained, the present invention is not limited thereto. The present invention may be applied to a configuration in which the stress adjustment layer is provided on the electroluminescence element side of the base material, two stress adjustment layers are provided sandwiching the base material therebetween, or the like.

### INDUSTRIAL APPLICABILITY

The present invention is useful for an electroluminescence device with excellent reliability capable of preventing deterioration of the electroluminescent element even in a case where the stated electroluminescence device is bent.

### REFERENCE SIGNS LIST

1 Organic EL display device
2 Hard coat film
9 First sealing film
10 Organic EL element
11 TFT layer
12 First moisture-proof film
13 Base material
15 Stress adjustment layer
17 Second moisture-proof film
18 Second sealing film
C, C1, C2, C3 Neutral face

1. An electroluminescence device comprising:
a base material being flexible; and
a plurality of layers including an electroluminescence element, provided on the base material, the plurality of layers further including:
a first moisture-proof film provided on a surface on the electroluminescence element side of the base material;
a TFT layer provided on a surface on the electroluminescence element side of the first moisture-proof film, the TFT layer including a thin film transistor configured to perform switching operation on the electroluminescence element;
a first sealing film provided to cover the electroluminescence element and configured to seal the electroluminescence element;
a hard coat film configured to protect a surface of the electroluminescence device; and
a stress adjustment layer configured to adjust a neutral face of the electroluminescence device,
wherein the neutral face is positioned between a lower face of the first moisture-proof film and an upper face of the first sealing film.

2. The electroluminescence device according to claim 1,
wherein the neutral face is set to an intermediate position between the lower face of the first moisture-proof film and the upper face of the first sealing film.

3. The electroluminescence device according to claim 1,
wherein Young's modulus and a thickness of each of the plurality of layers are set to make a distortion rate of each of the first moisture-proof film and the first sealing film become not greater than 1% when the electroluminescence device is bent with a radius of curvature of 0.5 mm, where the radius of curvature is a radius in a thickness direction of the electroluminescence device.

4. The electroluminescence device according to claim 1,
wherein the plurality of layers further include a second moisture-proof film provided on a surface of the base material on an opposite side to the electroluminescence element side, and
the neutral face is positioned between a lower face of the second moisture-proof film and the upper face of the first sealing film.

5. The electroluminescence device according to claim 4,
wherein the neutral face is set to an intermediate position between the lower face of the second moisture-proof film and the upper face of the first sealing film.

6. The electroluminescence device according to claim 4,
wherein Young's modulus and a thickness of each of the plurality of layers are set to make a distortion rate of each of the first moisture-proof film, the first sealing film, and the second moisture-proof film become not greater than 1% when the electroluminescence device is bent with a radius of curvature of 1.1 mm, where the radius of curvature is a radius in a thickness direction of the electroluminescence device.

7. The electroluminescence device according to claim 1,
wherein the plurality of layers further include a second sealing film provided in an upper portion of the first sealing film, the second sealing film being configured to seal the electroluminescence element, and
the neutral face is positioned between the lower face of the first moisture-proof film and an upper face of the second sealing film.

8. The electroluminescence device according to claim 7,
wherein the neutral face is set to an intermediate position between the lower face of the first moisture-proof film and the upper face of the second sealing film.

9. The electroluminescence device according to claim 7,
wherein Young's modulus and a thickness of each of the plurality of layers are set to make a distortion rate of each of the first moisture-proof film, the first sealing film, and the second sealing film become not greater than 1% when the electroluminescence device is bent with a radius of curvature of 0.8 mm, where the radius of curvature is a radius in a thickness direction of the electroluminescence device.

10. The electroluminescence device according to claim 1,
wherein the plurality of layers further include a second moisture-proof film provided on a surface of the base material on the opposite side to the electroluminescence element side and a second sealing film provided in an upper portion of the first sealing film, the second sealing film being configured to seal the electroluminescence element, and
the neutral face is positioned between a lower face of the second moisture-proof film and an upper face of the second sealing film.

11. The electroluminescence device according to claim 10,
wherein the neutral face is set to an intermediate position between the lower face of the second moisture-proof film and the upper face of the second sealing film.

12. The electroluminescence device according to claim 10,
wherein Young's modulus and a thickness of each of the plurality of layers are set to make a distortion rate of each of the first moisture-proof film, the first sealing film, the second moisture-proof film, and the second sealing film become not greater than 1% when the electroluminescence device is bent with a radius of curvature of 1.5 mm, where the radius of curvature is a radius in a thickness direction of the electroluminescence device.

13. The electroluminescence device according to claim 1,
wherein Young's modulus and a thickness of each of the plurality of layers are set to make a distortion rate of each of the hard coat film and the stress adjustment layer become not greater than 4% when the electroluminescence device is bent with a radius of curvature of 3.0 mm, where the radius of curvature is a radius in the thickness direction of the electroluminescence device.

14. The electroluminescence device according to claim 1,
wherein the hard coat film is formed of a hard coat layer and a base material layered together, or formed of only a hard coat layer.
